(19) United States
(12) Patent Application Publication
(10) Pub. No.: US 2025/0088152 A1
(43) Pub. Date: Mar. 13, 2025

(54) RADIO FREQUENCY AMPLIFICATION CIRCUIT, RADIO FREQUENCY TRANSCEIVER, AND COMMUNICATION DEVICE

(71) Applicants: HUAWEI TECHNOLOGIES CO., LTD., Shenzhen (CN); TSINGHUA UNIVERSITY, Beijing (CN)

(72) Inventors: Fuyuan Zhao, Beijing (CN); Wei Deng, Beijing (CN); Mingming Zhang, Shanghai (CN); Qilin Qiu, Shenzhen (CN)

(73) Assignees: HUAWEI TECHNOLOGIES CO., LTD., Shenzhen (CN); TSINGHUA UNIVERSITY, Beijing (CN)

(21) Appl. No.: 18/957,369

(22) Filed: Nov. 22, 2024

Related U.S. Application Data
(63) Continuation of application No. PCT/CN2023/093669, filed on Feb. 11, 2023.

(30) Foreign Application Priority Data
May 23, 2022 (CN) 202210563667.7

(51) Int. Cl. H03F 3/24; H01Q 1/24; H03F 1/56; H04B 1/00

(52) U.S. Cl. CPC H03F 3/245; H01Q 1/24; H03F 1/56; H04B 1/0053; H03F 2200/222; H03F 2200/387; H03F 2200/451

(57) ABSTRACT

This application discloses a radio frequency transceiver, and a communication device. A radio frequency amplification circuit includes two transmission paths disposed between a radio frequency input end and a radio frequency output end. The two transmission paths include a first transmission path and a second transmission path. The first transmission path includes a first amplifier, a first coil, a second coil, and a second amplifier that are sequentially coupled. The second transmission path includes a third amplifier, a third coil, a fourth coil, and a fourth amplifier that are sequentially coupled. Any two coils of the first coil, the second coil, the third coil, and the fourth coil are magnetically coupled. The first amplifier and the second amplifier is adjustable, or The third amplifier and the fourth amplifier is adjustable.

### CROSS-REFERENCE TO RELATED APPLICATIONS

This application is is a continuation of International Application No. PCT/CN2023/093669, filed on May 11, 2023, which claims priority to Chinese Patent Application No. 202210563667.7, filed on May 23, 2022. The disclosures of the aforementioned applications are hereby incorporated by reference in their entireties.

### TECHNICAL FIELD

Embodiments of this application relate to the field of communication technologies, and in particular, to a radio frequency amplification circuit, a radio frequency transceiver, and a communication device.

### BACKGROUND

A radio frequency transceiver includes a transmit path and a receive path. The transmit path is configured to transmit a radio frequency signal, and the receive path is configured to receive a radio frequency signal. With development of spectrum resources, a multi-band system including a plurality of operating frequency bands emerges. Because a frequency band corresponding to the transmit path or the receive path is a fixed value in the conventional technology, the radio frequency transceiver cannot support the multi-band system. Therefore, there is a need to design a radio frequency transceiver that can support the multi-band system.

### SUMMARY

Embodiments of this application provide a radio frequency amplification circuit, a radio frequency transceiver, and a communication device, to resolve a problem that an existing radio frequency transceiver supports a fixed frequency band and cannot support operation of a multi-band system.

To achieve the foregoing objectives, the following technical solutions are used in embodiments of this application.

A first aspect of embodiments of this application provides a radio frequency amplification circuit. The radio frequency amplification circuit may be applied to a transmit path or a receive path. The radio frequency amplification circuit includes a radio frequency input end, a radio frequency output end, and at least two transmission paths disposed between the radio frequency input end and the radio frequency output end. The at least two transmission paths include a first transmission path and a second transmission path. The first transmission path includes a first amplifier, a first coil, a second coil, and a second amplifier that are sequentially coupled. The second transmission path includes a third amplifier, a third coil, a fourth coil, and a fourth amplifier that are sequentially coupled. Any two coils of the first coil, the second coil, the third coil, and the fourth coil are magnetically coupled to each other. Turn-on or turn-off of the first amplifier and the second amplifier is adjustable, or turn-on or turn-off of the third amplifier and the fourth amplifier is adjustable.

According to the radio frequency amplification circuit provided in this embodiment of this application, a plurality of transmission paths are disposed between the radio frequency input end and the radio frequency output end. The plurality of transmission paths include a plurality of magnetically coupled coils. Turn-on or turn-off of an amplifier in the transmission path is adjusted, so that conduction or cut-off of the transmission path is controlled, to change an equivalent inductance of any coil in the radio frequency amplification circuit. In addition, a corresponding equivalent capacitor is provided by using a coil or the amplifier, so that a resonance frequency of the radio frequency amplification circuit can be changed. Therefore, the radio frequency amplification circuit can support more types of multi-band systems. In addition, according to the radio frequency amplification circuit provided in this embodiment of this application, an equivalent inductor and an equivalent capacitor are both adjusted, and a value of the equivalent inductor matches a value of the equivalent capacitor. This can ensure that a quality factor remains unchanged, and therefore can ensure a relatively stable bandwidth. In comparison with a radio frequency transmitter in the conventional technology, when a single transmit path or a single receive path in the radio frequency transmitter uses the radio frequency amplification circuit, a plurality of transmission paths are disposed in the radio frequency amplification circuit, so that a multi-band system can be supported. A plurality of transmit paths or a plurality of receive paths do not need to be independently disposed, and another component on the transmit path or the receive path does not need to be disposed, for example, a matching network, a filter, or another component. Therefore, a size of the radio frequency transmitter can be reduced, and costs can be reduced.

With reference to the first aspect, in a possible implementation, when any transmission path of the first transmission path and the second transmission path is conducted, the radio frequency amplification circuit is configured to amplify a first radio frequency signal. When the first transmission path and the second transmission path are both conducted, the radio frequency amplification circuit is configured to amplify a second radio frequency signal. A frequency of the first radio frequency signal is higher than a frequency of the second radio frequency signal.

According to the radio frequency amplification circuit provided in this embodiment of this application, the equivalent inductor and the equivalent capacitor in the radio frequency amplification circuit are changed through conduction or cut-off of the transmission path. Therefore, the resonance frequency of the radio frequency amplification circuit can be changed, and the radio frequency amplification circuit can support more types of multi-band systems.

With reference to the first aspect, in a possible implementation, an inductance value of the first coil is equal to an inductance value of the third coil, and an inductance value of the second coil is equal to an inductance value of the fourth coil.

With reference to the first aspect, in a possible implementation, a mutual inductance between the first coil and the second coil is equal to a mutual inductance between the third coil and the fourth coil; and/or a mutual inductance between the first coil and the third coil is equal to a mutual inductance between the second coil and the fourth coil; and/or a mutual inductance between the first coil and the fourth coil is equal to a mutual inductance between the second coil and the third coil.

With reference to the first aspect, in a possible implementation, the first amplifier and the third amplifier are amplifiers whose amplification factors are the same, and the second amplifier and the fourth amplifier are amplifiers whose amplification factors are the same.

According to the radio frequency amplification circuit provided in this embodiment of this application, a first coil L1 to a fourth coil L4 are symmetrically disposed, inductance values of the first coil L1 to the fourth coil L4 are set to a same value, mutual inductances between the coils are set to a same value, and amplification factors of amplifiers are set to a same value, so that radio frequency signals obtained after power amplification in the first transmission path and the second transmission path have a same amplitude, and signals output by the first transmission path and the second transmission path can be better fused.

With reference to the first aspect, in a possible implementation, the at least two transmission paths further include a third transmission path, the third transmission path includes a fifth amplifier, a fifth coil, a sixth coil, and a sixth amplifier, and any two coils of the first coil, the second coil, the third coil, the fourth coil, the fifth coil, and the sixth coil are magnetically coupled to each other.

According to the radio frequency amplification circuit provided in this embodiment of this application, conduction or cut-off of at least two transmission paths is adjusted, so that the equivalent inductor and the equivalent capacitor of the radio frequency amplification circuit can be adjusted, to adjust the resonance frequency of the radio frequency amplification circuit. When the radio frequency amplification circuit includes a plurality of transmission paths, the resonance frequency of the radio frequency amplification circuit may be adjusted to a plurality of values, so that the radio frequency amplification circuit can support a plurality of types of multi-band systems.

With reference to the first aspect, in a possible implementation, the first coil, the second coil, the third coil, the fourth coil, the fifth coil, and the sixth coil are symmetrically disposed at at least one trace layer.

According to the radio frequency amplification circuit provided in this embodiment of this application, the first coil to the sixth coil are symmetrically disposed at the at least one trace layer, so that any two coils of the first coil to the sixth coil are magnetically coupled to each other. Conduction or cut-off of the first transmission path to the third transmission path is controlled, so that an inductance value of any coil in the radio frequency amplification circuit can be adjusted, and the resonance frequency of the radio frequency amplification circuit can be changed. In this way, the radio frequency amplification circuit can support a plurality of types of multi-band systems.

With reference to the first aspect, in a possible implementation, the radio frequency amplification circuit further includes an input matching network and an output matching network. The input matching network is coupled between the radio frequency input end and the at least two transmission paths, and the output matching network is coupled between the radio frequency output end and the at least two transmission paths.

According to the radio frequency amplification circuit provided in this embodiment of this application, the input matching network and the output matching network are disposed, so that output power of the radio frequency amplification circuit can be maximized.

A second aspect of embodiments of this application provides a radio frequency transceiver. The radio frequency transceiver includes a transmitter and/or a receiver. The transmitter and/or the receiver include/includes a radio frequency amplification circuit and a filter that are sequentially coupled. The radio frequency amplification circuit is the radio frequency amplification circuit according to any one of the first aspect or the possible implementations of the first aspect.

With reference to the second aspect, in a possible implementation, the radio frequency transceiver includes the transmitter, a radio frequency amplification circuit included in the transmitter is a first radio frequency amplification circuit, a filter included in the transmitter is a first filter, and an output end of the first radio frequency amplification circuit is coupled to an input end of the first filter.

With reference to the second aspect, in a possible implementation, the transmitter further includes a first baseband processing circuit and an up-conversion circuit. An output end of the up-conversion circuit is coupled to an input end of the first radio frequency amplification circuit, and an input end of the up-conversion circuit is coupled to an output end of the first baseband processing circuit.

With reference to the second aspect, in a possible implementation, the radio frequency transceiver includes the receiver, a radio frequency amplification circuit included in the receiver is a second radio frequency amplification circuit, a filter included in the receiver is a second filter, and an output end of the second filter is coupled to an input end of the second radio frequency amplification circuit.

With reference to the second aspect, in a possible implementation, the receiver further includes a down-conversion circuit and a second baseband processing circuit. An input end of the down-conversion circuit is coupled to an output end of the second radio frequency amplification circuit, and an output end of the down-conversion circuit is coupled to an input end of the second baseband processing circuit.

According to a third aspect of embodiments of this application, a communication device is provided. The communication device includes an antenna and a radio frequency transceiver coupled to the antenna. The antenna is configured to transmit or receive a radio frequency signal. The radio frequency transceiver is the radio frequency transceiver according to any one of the second aspect or the possible implementations of the second aspect.

For descriptions of the second aspect and the third aspect in this application, refer to detailed descriptions of the first aspect. In addition, for beneficial effect of the second aspect and the third aspect, refer to analysis of beneficial effect of the first aspect. Details are not described herein again.

### BRIEF DESCRIPTION OF DRAWINGS

FIG. 1 is a schematic of a structure of a radio frequency transceiver according to an embodiment of this application;

FIG. 2 is a schematic of a structure of a radio frequency amplification circuit according to an embodiment of this application;

FIG. 3 is a schematic of a structure of a multi-band matching network according to an embodiment of this application;

FIG. 4 is a schematic of a structure of another radio frequency amplification circuit according to an embodiment of this application;

FIG. 5 is a schematic of a structure of a tunable frequency-selective network according to an embodiment of this application;

FIG. 6 is a schematic of a structure of an ideal parallel RLC resonance network according to an embodiment of this application;

FIG. 7 is a schematic of a structure of a resonance cavity parallel circuit according to an embodiment of this application;

FIG. 8 is a schematic of a structure of a parallel resonance circuit according to an embodiment of this application;

FIG. 9 is a schematic of a structure of a transformer matching network according to an embodiment of this application;

FIG. 10 is a schematic of a structure of another transformer matching network according to an embodiment of this application;

FIG. 11 is a schematic of a structure of still another transformer matching network according to an embodiment of this application;

FIG. 12 is a schematic of a structure of still another radio frequency amplification circuit according to an embodiment of this application;

FIG. 13 is a schematic of a structure of yet another radio frequency amplification circuit according to an embodiment of this application;

FIG. 14 is a schematic of a structure of still yet another radio frequency amplification circuit according to an embodiment of this application;

FIG. 15 is a schematic of a structure of a further radio frequency amplification circuit according to an embodiment of this application;

FIG. 16 is a diagram of a structure of a radio frequency transceiver according to an embodiment of this application; and

FIG. 17 is a diagram of a structure of a communication device according to an embodiment of this application.

### DESCRIPTION OF EMBODIMENTS

The making and use of embodiments are discussed in detail below. However, it should be understood that many applicable inventive concepts provided in this application may be implemented in a plurality of specific environments. The specific embodiments discussed are merely illustrative of specific manners to implement and use this description and this technology, and do not limit the scope of this application.

Unless otherwise defined, all technical terms used in this specification have same meaning as those commonly known to a person of ordinary skill in the art.

Each circuit or another component may be described as or referred to as “configured to” perform one or more tasks. In this case, the term “configured to” is used for implying a structure by indicating that a circuit/component includes a structure (for example, a circuit system) that performs one or more tasks during operation. Therefore, even when the specified circuit/component is currently not operable (for example, not turned on), the circuit/component may also be referred to as being configured to perform the task. The circuit/component used in conjunction with the “configured to” phrase includes hardware, for example, a circuit for performing an operation.

The following describes technical solutions in embodiments of this application with reference to the accompanying drawings in embodiments of this application. In this application, “at least one” means one or more, and “a plurality of” means two or more. “And/or” describes an association relationship between associated objects, and indicates that three relationships may exist. For example, A and/or B may indicate the following cases: Only A exists, both A and B exist, and only B exists, where A and B each may be singular or plural. A character “/” generally indicates an “or” relationship between the associated objects. “At least one of the following items (pieces)” or a similar expression thereof indicates any combination of these items, including a single item (piece) or any combination of a plurality of items (pieces). For example, at least one item (piece) of a, b, or c may indicate: a, b, c, a and b, a and c, b and c, or a, b, and c, where a, b, and c may be singular or plural. In addition, in embodiments of this application, terms such as “first” and “second” do not limit a quantity or an execution sequence.

It should be noted that, in this application, terms such as “example” or “for example” indicate giving an example, an illustration, or a description. Any embodiment or design scheme described as an “example” or “for example” in this application should not be explained as being more preferred or having more advantages than another embodiment or design scheme. Exactly, use of the term “example”, “for example”, or the like is intended to present a related concept in a specific manner.

Before descriptions of embodiments of this application, a background technology related to this application is first described.

A radio frequency transceiver is a front-end part in a communication system, and usually includes a transmit path and a receive path. The transmit path is configured to transmit a radio frequency signal, and the receive path is configured to receive a radio frequency signal. With development of spectrum resources, a multi-band system including a plurality of operating frequency bands emerges. Because the multi-band system has advantages of adaptability and scalability, designing a radio frequency transceiver that can support the multi-band system becomes a main development direction.

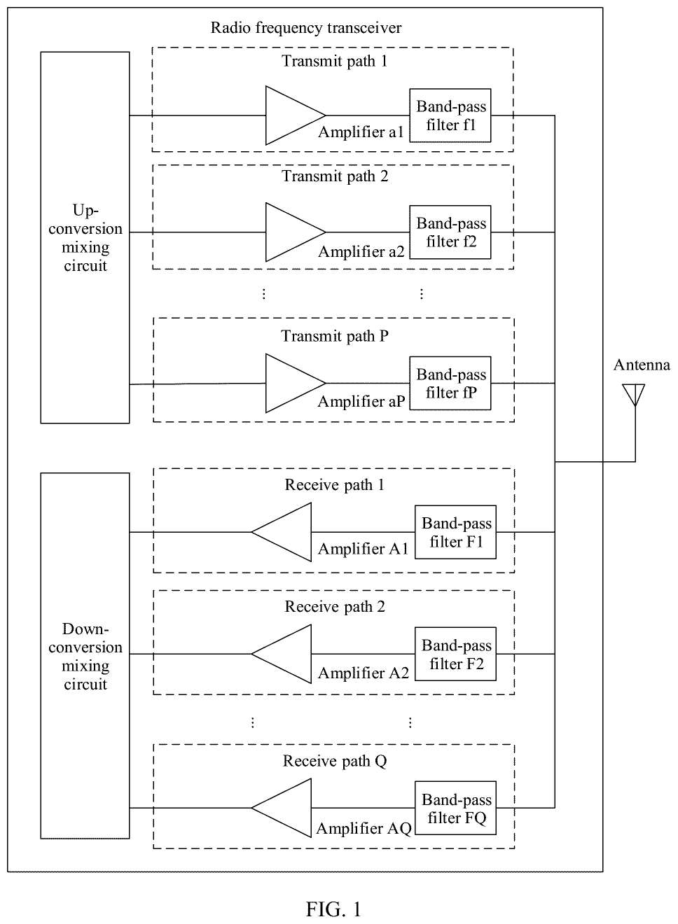

FIG. 1 shows a radio frequency transceiver. A plurality of transmit paths and a plurality of receive paths are separately disposed, so that the radio frequency transceiver implements sending or receiving of radio frequency signals of different frequency bands, to support a multi-band system. The radio frequency transceiver includes an up-conversion mixing circuit, a down-conversion mixing circuit, a transmit path 1 to a transmit path P, a receive path 1 to a receive path Q, and another component. Each transmit path or receive path is coupled to an antenna. P and Q each are an integer greater than 1. Each transmit path or receive path is used for transmission of a radio frequency signal of a fixed frequency band, and components such as an amplifier and a filter that correspond to the frequency band are disposed in each transmit path or receive path. An input end of the amplifier may be equivalent to a radio frequency input end described in the following embodiment, and an output end of the amplifier may be equivalent to a radio frequency output end described in the following embodiment. The radio frequency input end is configured to input a radio frequency signal, the amplifier is configured to amplify the radio frequency signal, and the radio frequency output end is configured to output an amplified radio frequency signal.

For example, the transmit path 1 is used for transmission of a radio frequency signal whose frequency band is f1. The transmit path 1 may include an amplifier al and a band-pass filter f1. The transmit path P is used for transmission of a radio frequency signal whose frequency band is fP. The transmit path P may include an amplifier aP and a band-pass filter fP. The receive path 1 is used for transmission of a radio frequency signal whose frequency band is F1. The receive path 1 may include an amplifier A1 and a band-pass filter F1. The receive path Q is used for transmission of a radio frequency signal whose frequency band is FQ. The receive path Q may include an amplifier AQ and a band-pass filter FQ.

The up-conversion mixing circuit is configured to generate a radio frequency signal based on the baseband signal. Amplifiers corresponding to the transmit path 1 to the transmit path P are configured to perform power amplification processing on the radio frequency signal. A radio frequency signal obtained after power amplification processing may be sent by using the antenna. The antenna may be further configured to receive a radio frequency signal. Amplifiers corresponding to the receive path 1 to the receive path Q are configured to perform power amplification processing on the radio frequency signal. The down-conversion mixing circuit is configured to generate a baseband signal based on a radio frequency signal obtained after power amplification processing.

However, when a type of the multi-band system changes, for example, when a fourth generation wireless system changes to a fifth generation wireless system, an operating frequency band included in a changed multi-band system also changes. Because a frequency band corresponding to each transmit path or receive path is a fixed value, the radio frequency transceiver cannot continue to support the multi-band system whose type changes. In addition, in the radio frequency transceiver, when the multi-band system includes a plurality of frequency bands, a plurality of transmit paths or a plurality of receive paths need to be independently disposed. Each transmit path or receive path corresponds to one frequency band. Components such as an amplifier and a filter that correspond to the transmission frequency band are disposed in each path, which causes a large size and high costs of the radio frequency transceiver.

To adjust the frequency band supported by the radio frequency transceiver, reduce a size of the radio frequency transceiver, and reduce costs, the transmit path and the receive path in the radio frequency transceiver need to be redesigned.

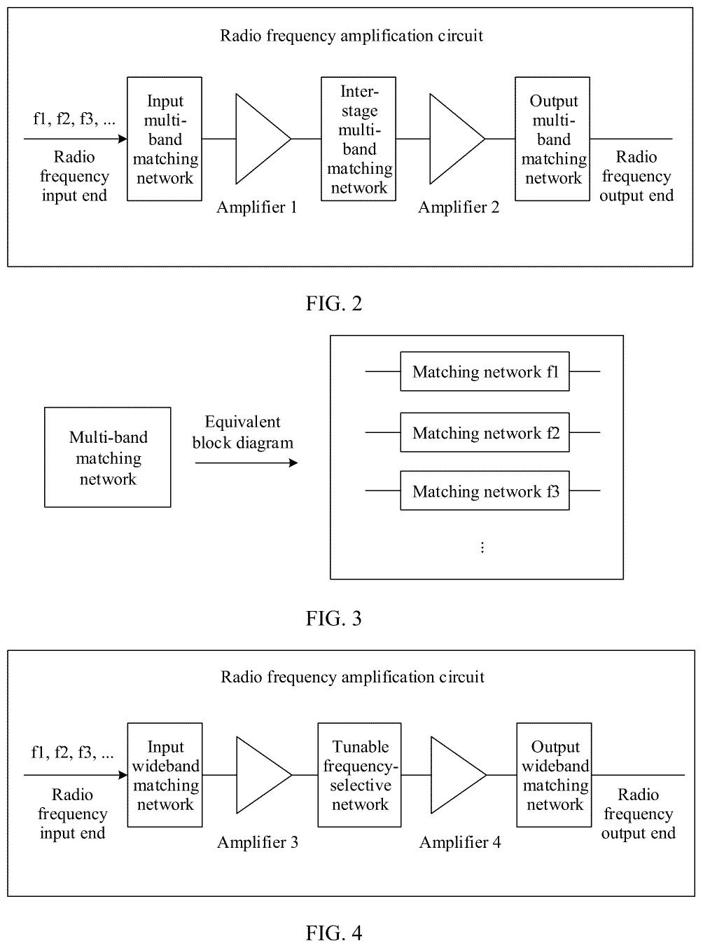

FIG. 2 shows a radio frequency amplification circuit. An input end of the radio frequency amplification circuit is a radio frequency input end, and an output end of the radio frequency amplification circuit is a radio frequency output end. The radio frequency amplification circuit may be configured to replace the amplifier in the transmit path, or may be configured to replace the amplifier in the receive path. A multi-band matching network is disposed, so that the radio frequency amplification circuit implements sending or receiving of radio frequency signals of different frequency bands. Specifically, the radio frequency amplification circuit includes an input multi-band matching network, an amplifier 1, an inter-stage multi-band matching network, an amplifier 2, and an output multi-band matching network that are sequentially coupled. The input multi-band matching network is configured to receive radio frequency signals of a plurality of frequency bands (for example, radio frequency signals of frequency bands such as f1, f2, and f3). The output multi-band matching network is configured to output radio frequency signals of a plurality of frequency bands. The input multi-band matching network and the output multi-band matching network are configured to maximize output power of the radio frequency amplification circuit. The inter-stage multi-band matching network is configured to maximize output gains of the radio frequency amplification circuit. The amplifier 1 and the amplifier 2 are configured to amplify power of the radio frequency signal.

In the radio frequency amplification circuit shown in FIG. 2, the multi-band matching network is disposed, so that one path can support transmission of radio frequency signals of a plurality of frequency bands. In comparison with the radio frequency transceiver shown in FIG. 1, in a radio frequency transceiver using the radio frequency amplification circuit shown in FIG. 2, a plurality of transmit paths or a plurality of receive paths does not need to be separately disposed, so that a quantity of amplifiers can be reduced, thereby reducing a size of the radio frequency transceiver and reducing costs. However, a matching network corresponding to each frequency band is usually included inside the multi-band matching network in the radio frequency amplification circuit. For example, as shown in FIG. 3, the multi-band matching network includes: a matching network f1 corresponding to the frequency band f1, a matching network f2 corresponding to the frequency band f2, a matching network f3 corresponding to the frequency band f3, and another matching network, where the matching network includes a capacitor, a resistor, an inductor, a transformer, and another component.

To implement that the frequency band supported by the radio frequency transceiver can be adjusted, further reduce a size of the radio frequency amplification circuit, and reduce costs, the inter-stage multi-band matching network in the radio frequency amplification circuit may be reset to a tunable frequency-selective network, and the input multi-band matching network and the output multi-band matching network may be reset to a wideband matching network.

FIG. 4 shows a radio frequency amplification circuit according to an embodiment of this application. An input end of the radio frequency amplification circuit is a radio frequency input end, and an output end of the radio frequency amplification circuit is a radio frequency output end. The radio frequency amplification circuit includes an input wideband matching network, an amplifier 3, a tunable frequency-selective network, an amplifier 4, and an output wideband matching network that are sequentially coupled. A resonance frequency of the tunable frequency-selective network is adjustable, so that a frequency band supported by the radio frequency amplification circuit can be adjusted, and a frequency band supported by a radio frequency transceiver can be adjusted.

For example, FIG. 5 shows a tunable frequency-selective network. The tunable frequency-selective network adjusts a resonance frequency by using a tunable capacitor whose capacitance value is adjustable. The tunable capacitor includes a switch capacitor 1 to a switch capacitor 6. A switch and a capacitor that correspond to each other are included inside each switch capacitor. Turn-on or turn-off of a switch is adjusted, so that a corresponding switch capacitor is turned on or turned off, to adjust a capacitance value of the tunable capacitor. In this way, a capacitance value of an equivalent capacitor of the tunable frequency-selective network is adjusted, to adjust the frequency band supported by the radio frequency amplification circuit.

The tunable capacitor may be a multi-bit (bit) tunable capacitor (or may be referred to as a digital programmable capacitor). For example, the multi-bit tunable capacitor may include eight switch capacitors, and the eight switch capacitors may perform encoding by using a binary number of 3 bits. A switch and a capacitor that correspond to each other are included inside each switch capacitor. Turn-on or turn-off of a switch is adjusted, so that a corresponding switch capacitor is turned on or turned off, to adjust a capacitance value of the multi-bit tunable capacitor.

In the radio frequency amplification circuit shown in FIG. 4, the input wideband matching network, the tunable frequency-selective network, and the output wideband matching network are disposed, so that the frequency band supported by the radio frequency amplification circuit can be adjusted. In addition, in comparison with the radio frequency transceiver shown in FIG. 1, a plurality of transmit paths and a plurality of receive paths do not need to be separately disposed. Therefore, a size of the radio frequency amplification circuit can be reduced, and costs can be reduced.

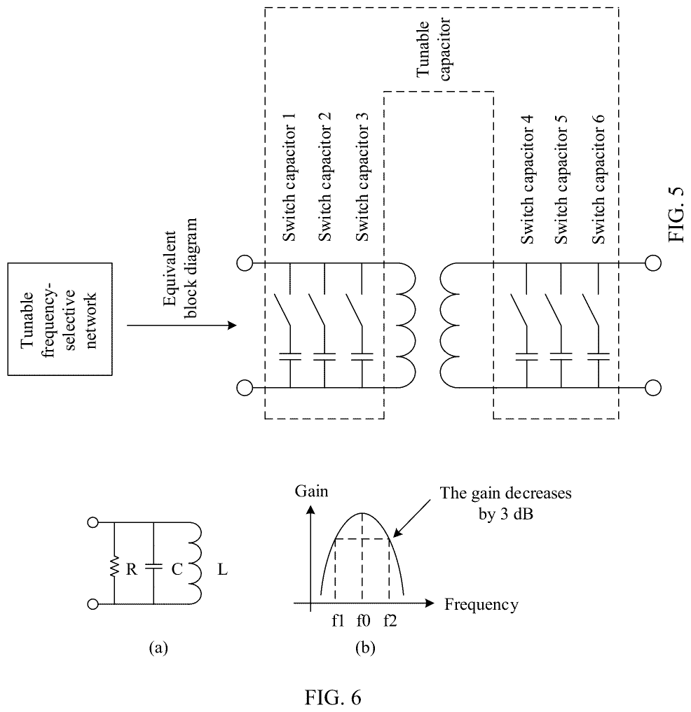

The following uses an ideal parallel RLC resonance network shown in (a) in FIG. 6 as an example, to describe in detail a principle of the tunable frequency-selective network. The ideal parallel RLC resonance network includes a resistor R, a capacitor C, and an inductor L that are disposed in parallel. In the parallel RLC resonance network, a formula for calculating a resonance frequency is:

$$f = \frac{1}{2 π \sqrt{LC}}$$

Herein, f indicates the resonance frequency, L is an inductance value of the inductor L, and C is a capacitance value of the inductor C. When the capacitance value of the capacitor C increases, or the inductance value of the inductor L increases, the resonance frequency of the ideal parallel RLC resonance network decreases. When the capacitance value of the capacitor C decreases, or the inductance value of the inductor L decreases, the resonance frequency of the ideal parallel RLC resonance network increases.

In the parallel RLC resonance network, a formula for calculating an angular frequency is:

$$ω = 2 π f = \frac{1}{\sqrt{LC}}$$

Herein, ω indicates the angular frequency. When the capacitance value of the capacitor C increases, or the inductance value of the inductor L increases, a value of the angular frequency ω decreases. When the capacitance value of the capacitor C decreases, or the inductance value of the inductor L decreases, a value of the angular frequency ω increases.

In a resonance circuit, a quality factor (or referred to as a quality divisor, or referred to as a quality element) Q indicates a quality index of a ratio of energy stored by an energy storage component (such as the inductor L or the capacitor C) to energy lost in each period. A larger Q value of the component indicates better selectivity of a circuit or network including the element. In the ideal parallel RLC resonance network, with reference to the foregoing formulas for calculating the resonance frequency and the angular frequency, a formula for calculating the quality factor Q may be expressed as:

$$Q = R ω C = \frac{R}{ω L} = R \frac{\sqrt{C}}{\sqrt{L}}$$

Herein, R is a resistance value of the resistor R. It can be learned from the foregoing formula that, in a case in which the resistance value of the resistor R remains unchanged, a larger capacitance value of the capacitor C or a smaller inductance value of the inductor L indicates a larger value of the quality factor Q. In a case in which the resistance value of the resistor R remains unchanged, a smaller capacitance value of the capacitor C or a larger inductance value of the inductor L indicates a smaller value of the quality factor Q.

In a resonance network, when a gain of a radio frequency signal decreases by 3 dB, an interval determined by two corresponding frequencies is generally used as a bandwidth, and a resonance frequency is a center frequency of the bandwidth. For example, as shown in (b) in FIG. 6, when a gain of a radio frequency signal decreases by 3 dB, a corresponding frequency f1 and a corresponding frequency f2 are used. In this case, a bandwidth of the resonance network is f2-f1, and the resonance frequency of the resonance network is f0. A width of the bandwidth is related to the value of the quality factor Q. In the ideal parallel RLC resonance network, with reference to the foregoing formulas for calculating the resonance frequency, the angular frequency, and the quality factor, a formula for calculating the bandwidth may be expressed as:

$$BW = \frac{ω}{Q}$$

Herein, BW indicates the bandwidth. According to the foregoing formula for calculating the bandwidth BW and with reference to formulas for calculating the angular frequency ω and the quality factor Q, a larger capacitance value of the capacitor C indicates a smaller value of the angular frequency ω, a larger value of the quality factor Q, and a smaller bandwidth BW. A smaller capacitance value of the capacitor C indicates a larger value of the angular frequency ω, a smaller value of the quality factor Q, and a larger bandwidth BW.

It can be learned from the foregoing formula for calculating the resonance frequency that, in the tunable frequency-selective network shown in FIG. 5, a capacitance value of the switch capacitor is adjusted, so that the resonance frequency of the tunable frequency-selective network is changed. Specifically, the capacitance value of the switch capacitor is increased, so that the resonance frequency is decreased; or the capacitance value of the switch capacitor is decreased, so that the resonance frequency is increased. However, according to the foregoing formulas for calculating the angular frequency ω, the quality factor Q, and the bandwidth BW, when the capacitance C increases and the value of the angular frequency ω decreases, the value of the quality factor Q increases, and the bandwidth BW decreases; or when the capacitance C decreases and the value of the angular frequency ω increases, the value of the quality factor Q decreases, and the bandwidth BW increases. It may be understood that, in a process of adjusting the resonance frequency, the capacitance value of the capacitor is changed but the inductance value of the inductor is not changed. Because the quality factor Q changes, a bandwidth of a radio frequency amplification circuit to which the tunable frequency-selective network is applied fluctuates.

Further, to make the bandwidth of the tunable frequency-selective network stable, the inductance value of the inductor may be adjusted when the capacitance value of the capacitor is adjusted, so that the quality factor Q is stable, thereby ensuring that the bandwidth BW is relatively stable.

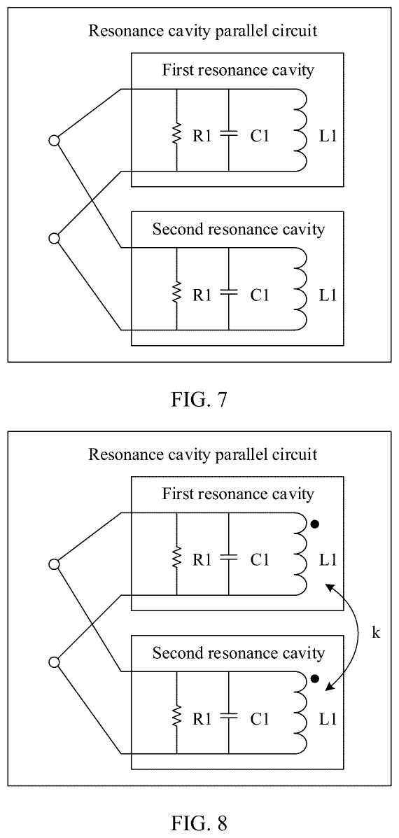

FIG. 7 shows a resonance cavity parallel circuit. A capacitance value of a capacitor is changed through parallel connection. The resonance cavity parallel circuit includes a first resonance cavity and a second resonance cavity. The first resonance cavity includes a resistor R1, a capacitor C1, and an inductor L1 that are coupled in parallel to each other. The second resonance cavity includes a resistor R2, a capacitor C2, and an inductor L2 that are coupled in parallel to each other. Resistance values of the resistor R1 and the resistor R2 are both R, capacitance values of the capacitor C1 and the capacitor C2 are both C, inductance values of the inductor L1 and the inductor L2 are both L, and resonance frequencies of two resonance cavities are both f0. With reference to the foregoing formula for calculating the resonance frequency, it can be learned that:

$$f 0 = \frac{1}{2 π \sqrt{LC}}$$

In the resonance cavity parallel circuit, a value of an equivalent capacitor and a value of an equivalent inductor may be expressed as the following formulas:

$${C}_{eq} = 2 C \\ {L}_{eq} = L / 2$$

Herein, C_{eq} indicates the value of the equivalent capacitor, L_{eq} indicates the value of the equivalent inductor. It can be learned with reference to the foregoing formula for calculating the resonance frequency that:

$$f 1 = \frac{1}{2 π \sqrt{{L}_{eq} {C}_{eq}}} = \frac{1}{2 π \sqrt{L / 2 * 2 C}} = \frac{1}{2 π \sqrt{LC}}$$

It may be understood that the first resonance cavity and the second resonance cavity are coupled in parallel to each other, to form the resonance cavity parallel circuit. A resonance frequency f1 of the resonance cavity parallel circuit and the resonance frequency f0 of the first resonance cavity or the second resonance cavity are a same resonance frequency.

Inductors of the two resonance cavities are magnetically coupled to each other, so that the value of the equivalent inductor in the resonance parallel circuit changes, thereby adjusting the resonance frequency of the resonance parallel circuit. Specifically, when a magnetic flux of coupling between the two inductors is positive, in comparison with a case in which there is no magnetic coupling between the two inductors, a value of an equivalent inductor of the inductors increases, and the resonance frequency of the parallel resonance circuit decreases; or when a magnetic flux of coupling between the two inductors is negative, in comparison with a case in which there is no magnetic coupling between the two inductors, a value of an equivalent inductor of the inductors decreases, and the resonance frequency of the parallel resonance circuit increases.

FIG. 8 shows a parallel resonance circuit. The resonance cavity parallel circuit includes a first resonance cavity and a second resonance cavity. The first resonance cavity includes a resistor R1, a capacitor C1, and an inductor L1 that are coupled in parallel to each other. The second resonance cavity includes a resistor R2, a capacitor C2, and an inductor L2 that are coupled in parallel to each other. Resistance values of the resistor R1 and the resistor R2 are both R, capacitance values of the capacitor C1 and the capacitor C2 are both C, inductance values of the inductor L1 and the inductor L2 are both L. The inductor L1 and the inductor L2 are magnetically coupled to each other, and a coupling coefficient is k. When there is no magnetic coupling between the inductor L1 and the inductor L2 in two resonance cavities, resonance frequencies of the two resonance cavities are both f0, and a resonance frequency of the parallel resonance circuit is also f0. f0 may be expressed as:

$$f 0 = \frac{1}{2 π \sqrt{LC}}$$

In the resonance cavity parallel circuit, a value of an equivalent capacitor and a value of an equivalent inductor may be expressed as the following formulas:

$${C}_{eq} = 2 C \\ {L}_{eq} = ( L + M ) / 2 > L / 2$$

Herein, C_{eq} indicates the value of the equivalent capacitor, L_{eq} indicates the value of the equivalent inductor, and M indicates a mutual inductance between the inductor L1 and the inductor L2.

When the resonance frequency of the parallel resonance circuit needs to be adjusted to f1 (f1=+a·f0), the mutual inductance between the inductor L1 and the inductor L2 may be adjusted to:

$$M = L ( \frac{1}{α} - 1 )$$

Herein, M indicates the mutual inductance between the inductor L1 and the inductor L2, L indicates the inductance value of the inductor L1 or the inductor L2, and a indicates that the resonance frequency f1 is a times the resonance frequency f0.

In this case, the value L_{eq} of the equivalent inductance of the parallel resonance circuit may be expressed as the following formula:

$${L}_{eq} = \frac{L}{2 α}$$

Then, the value C_{eq} of the equivalent capacitance is adjusted, and a value C_{eq} that is of the equivalent capacitance and that is obtained after adjustment may be expressed as the following formula:

$${C}_{eq} = \frac{1}{α} \cdot 2 C$$

With reference to the foregoing formula for calculating the resonance frequency, it can be learned that the resonance frequency f1 of the parallel resonance circuit may be expressed as the following formula:

$$f 1 = \frac{1}{2 π \sqrt{{L}_{eq} {C}_{eq}}} = \frac{1}{2 π \sqrt{\frac{L}{2 α} \cdot \frac{1}{α} \cdot 2 C}} = \frac{α}{2 π \sqrt{LC}} = α \cdot f 0$$

It can be learned from the foregoing formula for calculating the quality factor Q that a quality factor Q1 of the parallel resonance circuit may be expressed as the following formula:

$$Q 1 = R \frac{\sqrt{{C}_{eq}}}{\sqrt{{L}_{eq}}} = R \frac{\sqrt{\frac{1}{α} \cdot 2 C}}{\sqrt{\frac{L}{2 α}}} = R \frac{\sqrt{C}}{\sqrt{L}} = Q$$

It can be learned from the foregoing formula for calculating the bandwidth BW that a bandwidth BW1 of the parallel resonance circuit may be expressed as the following formula:

$$BW 1 = \frac{ω 1}{Q 1} = \frac{ω 1}{Q}$$

It may be understood that, in the tunable frequency-selective network shown in FIG. 5, the capacitance value of the capacitor is changed, so that the resonance frequency of the tunable frequency-selective network is adjusted. However, the value of the quality factor of the tunable frequency-selective network is changed, resulting in relatively large bandwidth fluctuation at different resonance frequencies. However, in the resonance cavity parallel circuit shown in FIG. 8, when the inductance value of the inductor is adjusted, the capacitance value of the capacitor is correspondingly adjusted based on the inductance value of the inductor, so that the resonance frequency of the resonance cavity parallel circuit can be adjusted from f0 to f1, and the value of the quality factor of the resonance cavity parallel circuit is not changed, thereby ensuring that the bandwidth of the resonance cavity parallel circuit is relatively stable.

The foregoing principles are also applicable to a transformer matching network that is provided below and that includes coupled resonance cavities.

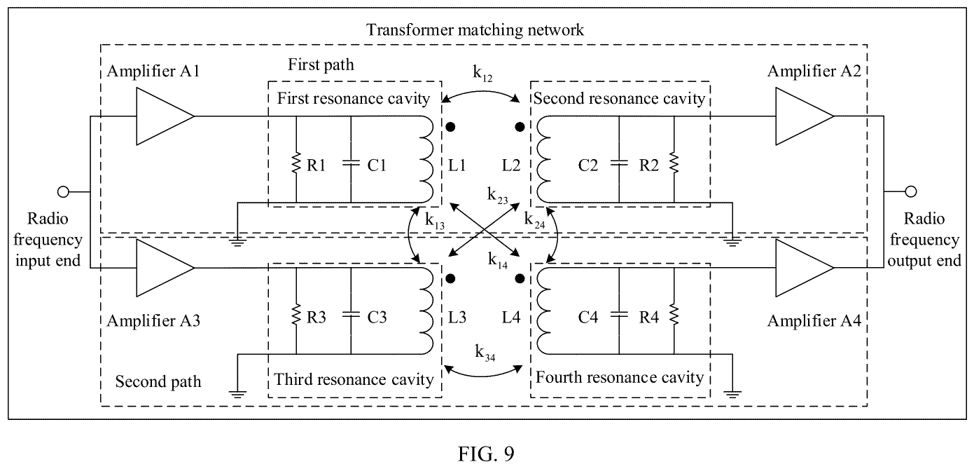

FIG. 9 shows a transformer matching network including coupled resonance cavities. The transformer matching network includes a first path and a second path. The first path includes an amplifier A1, a first resonance cavity, a second resonance cavity, and an amplifier A2. The first resonance cavity includes a resistor R1, a capacitor C1, and an inductor L1 that are coupled in parallel to each other. The second resonance cavity includes an inductor L2, a capacitor C2, and a resistor R2 that are coupled in parallel to each other. One end of the resistor R1 is coupled to one end of the amplifier A1, and the other end of the resistor R1 is coupled to a ground end. One end of the resistor R2 is coupled to one end of the amplifier A2, and the other end of the resistor R2 is coupled to a ground end. The second path includes an amplifier A3, a third resonance cavity, a fourth resonance cavity, and an amplifier A4. The third resonance cavity includes a resistor R3, a capacitor C3, and an inductor L3 that are coupled in parallel to each other. The fourth resonance cavity includes an inductor L4, a capacitor C4, and a resistor R4 that are coupled in parallel to each other. One end of the resistor R3 is coupled to one end of the amplifier A3, and the other end of the resistor R3 is coupled to a ground end. One end of the resistor R4 is coupled to one end of the amplifier A4, and the other end of the resistor R4 is coupled to a ground end. The other end of the amplifier A1 and the other end of the amplifier A3 are coupled to each other, to serve as a radio frequency input end. The other end of the amplifier A2 and the other end of the amplifier A4 are coupled to each other, to serve as a radio frequency output end.

Inductance values of the inductor L1 and the inductor L3 are equal, and inductance values of the inductor L2 and the inductor L4 are equal. Any two inductors of the inductor L1 to the inductor L4 are magnetically coupled to each other. A coupling coefficient between the inductor L1 and the inductor L2 is K₁₂. A coupling coefficient between the inductor L1 and the inductor L3 is K₁₃. A coupling coefficient between the inductor L1 and the inductor L4 is K₁₄. A coupling coefficient between the inductor L1 and the inductor L3 is K₁₃. A coupling coefficient between the inductor L2 and the inductor L3 is K₂₃. A coupling coefficient between the inductor L2 and the inductor L4 is K₂₄. The amplifier A1 and the amplifier A3 are amplifiers whose amplification factors are the same, and the amplifier A2 and the amplifier A4 are amplifiers whose amplification factors are the same. A path of a radio frequency signal from the amplifier A1 to the amplifier A2 is the first path, and a path of a radio frequency signal from the amplifier A3 to the amplifier A4 is the second path.

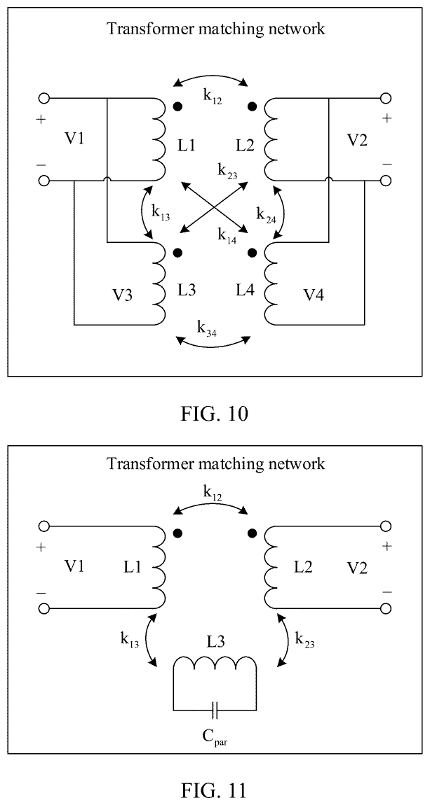

When the amplifier A1 to the amplifier A4 are all turned on, the first path and the second path are both conducted. An equivalent circuit corresponding to the transformer matching network shown in FIG. 9 may be as shown in FIG. 10. An I-V (current-voltage) characteristic matrix of the equivalent circuit may be expressed as the following formula:

$$[ \begin{matrix}{V}_{1} \\ {V}_{2} \\ {V}_{3} \\ {V}_{4}\end{matrix} ] = [ \begin{matrix}{L}_{1} & {M}_{12} & {M}_{13} & {M}_{14} \\ {M}_{12} & {L}_{2} & {M}_{23} & {M}_{24} \\ {M}_{13} & {M}_{23} & {L}_{3} & {M}_{34} \\ {M}_{14} & {M}_{24} & {M}_{34} & {L}_{4}\end{matrix} ] \cdot [ \begin{matrix}{I}_{1} \\ {I}_{2} \\ {I}_{3} \\ {I}_{4}\end{matrix} ]$$

Herein, a voltage V₁ to a voltage V₄ respectively indicate a voltage at two ends of the inductor L1 to a voltage at two ends of the inductor L4, s (or written as jo) indicates a phase relationship at a current frequency, L₁ to L₄ respectively indicate the inductance value of the inductor L1 to the inductance value of the inductor L4, a current I₁ to a current I₄ respectively indicate a current value of the inductor L1 to a current value of the inductor L4, M₁₂, and M₁₃ to M₃₄ each indicate a value of a mutual inductance between any two inductors of the inductor L1 to the inductor L4. The value of the mutual inductance may be calculated according to the following formula:

$${M}_{i j} = {K}_{i j} \sqrt{{L}_{i} \cdot {L}_{j}}$$

Herein, Mᵢⱼ indicates a value of a mutual inductance between an inductor Li and an inductor Lj, Kᵢⱼ indicates a coupling coefficient between the inductor Li and the inductor Lj, Lᵢ indicates an inductance value of the inductor Li, and Lⱼ indicates an inductance value of the inductor L.

Because the amplifier A1 and the amplifier A3 are amplifiers whose amplification factors are the same, and the amplifier A2 and the amplifier A4 are amplifiers whose amplification factors are the same, relationships between the voltage V₁ to the voltage V₄ may be expressed as the following formulas:

$${V}_{1} = {V}_{3} \\ {V}_{2} = {V}_{4}$$

A relationship among a voltage, a current, and a mutual inductance may be expressed as the following formula:

$$\dot{V} = \dot{M} \cdot \dot{I}$$

Herein, \dot{V} indicates a voltage vector, \dot{M} indicates a mutual inductance vector, and İ indicates a current vector. The I-V (current-voltage) characteristic matrix of the equivalent circuit may be simplified, according to the foregoing formula, into the following formula:

$$[ \begin{matrix}{V}_{1} \\ {V}_{2}\end{matrix} ] = s \cdot {\dot{M}}_{e q} [ \begin{matrix}{I}_{1} + {I}_{3} \\ {I}_{2} + {I}_{4}\end{matrix} ]$$

Herein, V₁ indicates the voltage at the two ends of the inductor L1, V₂ indicates the voltage at the two ends of the inductor L2, s (or written as jω) indicates the phase relationship at the current frequency, the current I₁ to the current I₄ respectively indicate the current value of the inductor L1 to the current value of the inductor L4, and \dot{M}_{eq} indicates an inductance value of an equivalent mutual inductance of the transformer matching network.

Because the inductance values of the inductor L1 and the inductor L3 are equal, and the inductance values of the inductor L2 and the inductor L4 are equal, the following formulas may be obtained:

$$\begin{matrix}{L}_{1} = {L}_{3} , {L}_{2} = {L}_{4} \\ {M}_{12} = {M}_{34} = {M}_{p} \\ {M}_{13} = {M}_{24} = {M}_{i} \\ {M}_{14} = {M}_{24} = {M}_{c}\end{matrix}$$

According to the foregoing formula, the inductance value M_{eq} of the equivalent mutual inductance of the transformer matching network may be obtained by using the following formula:

$$[ \begin{matrix}\frac{{L}_{1}}{2} + \frac{{M}_{i}}{2} & \frac{{M}_{c}}{2} + \frac{{M}_{p}}{2} \\ \frac{{M}_{c}}{2} + \frac{{M}_{p}}{2} & \frac{{L}_{2}}{2} + \frac{{M}_{i}}{2}\end{matrix} ]$$

It can be learned according to the foregoing formula that, when the amplifier A1 to the amplifier A4 are all turned on, the first path and the second path are both conducted, an equivalent mutual inductance of the inductor L1 of the transformer matching network is

$$\frac{{L}_{1}}{2} + \frac{{M}_{i}}{2} ,$$

and an inductance value of the equivalent mutual inductance is greater than

$$\frac{{L}_{1}}{2} .$$

However, the equivalent inductance value of the inductor L1 of the resonance cavity parallel circuit shown in FIG. 7 is L_{eq}=L/2. It can be learned with reference to the foregoing formula for calculating the resonance frequency that a resonance frequency of the transformer matching network is lower. It may be understood that, when the radio frequency amplification circuit uses the frequency converter matching network as a tunable frequency-selective network, a resonance frequency can be adjusted, a frequency band with a lower frequency can be supported, and a relatively stable bandwidth can be ensured.

With reference to FIG. 9, when the amplifier A1 and the amplifier A2 are turned on, and the amplifier A2 and the amplifier A3 are turned off, the first path is conducted, and the second path is cut off. An equivalent circuit corresponding to the transformer matching network shown in FIG. 9 may be as shown in FIG. 11. The transformer matching network includes the inductor L1 to the inductor L3, and a parasitic capacitor Cₚₐᵣ. A relationship in the equivalent circuit may be expressed as the following formula:

$$[ \begin{matrix}{V}_{1} \\ {V}_{2}\end{matrix} ] = [ \begin{matrix}{L}_{1} + \frac{{ω}^{2} {M}_{13}^{2}}{\frac{1}{C} - {ω}^{2} {L}_{3}} & {M}_{12} + \frac{{ω}^{2} {M}_{13} {M}_{23}}{\frac{1}{C} - {ω}^{2} {L}_{3}} \\ {M}_{12} + \frac{{ω}^{2} {M}_{13} {M}_{23}}{\frac{1}{C} - {ω}^{2} {L}_{3}} & {L}_{2} + \frac{{ω}^{2} {M}_{13}^{2}}{\frac{1}{C} - {ω}^{2} {L}_{3}}\end{matrix} ]$$

Herein, a voltage V₁ and a voltage V₂ indicate a voltage at two ends of the inductor L1 and a voltage at two ends of the inductor L2, L₁ and L₂ indicate an inductance value of the inductor L1 and an inductance value of the inductor L2, M₁₂, M₁₃, and the like indicate mutual inductances between the inductors, and C indicates a capacitance value Cₚₐᵣ of the parasitic capacitor. When the capacitance value Cₚₐᵣ of the parasitic capacitor is 0 or is infinite, an equivalent inductance value of the inductor L1 may be expressed as the following formula:

$${L}_{1} + \frac{{ω}^{2} {M}_{13}^{2}}{\frac{1}{C} - {ω}^{2} {L}_{3}} = \{ \begin{matrix}{L}_{1} - {K}_{13}^{2} {L}_{1} , C \to ∞ \\ \begin{matrix}{L}_{1} , & C \to 0\end{matrix}\end{matrix}$$

It can be learned according to the foregoing formula that, when the amplifier A1 and the amplifier A2 are turned on, and the amplifier A3 and the amplifier A4 are turned off, the first path is conducted, the second path is cut off, and the equivalent mutual inductance of the inductor L1 of the transformer matching network is

$${L}_{1} + \frac{{ω}^{2} {M}_{13}^{2}}{\frac{1}{C} - {ω}^{2} {L}_{3}} .$$

In comparison with the equivalent mutual inductance

$$\frac{{L}_{1}}{2} + \frac{{M}_{i}}{2}$$

that is of the inductor L1 of the transformer matching network and that is obtained when the amplifier A1 to the amplifier A4 are all turned on, and the first path and the second path are also conducted, the equivalent mutual inductance of the inductor L1 is relatively small. With reference to the foregoing formula for calculating the resonance frequency, it may be understood that when the first path is conducted and the second path is cut off, the transformer matching network has a relatively high resonance frequency and can support a frequency band with a relatively high frequency; or when the first path and the second path are both conducted, the transformer matching network has a relatively low resonance frequency and can support a frequency band with a relatively low frequency.

In conclusion, in the transformer matching network shown in FIG. 9, turning on and turning off of the amplifier are adjusted, so that an equivalent inductor of the inductor L1 is adjusted. In this way, the resonance frequency of the transformer matching network can be adjusted, and a relatively stable bandwidth can be ensured. In addition, in comparison with the radio frequency transmitter shown in FIG. 1, a plurality of transmit paths or a plurality of receive paths do not need to be independently disposed, and a large quantity of amplifiers and filters do not need to be disposed. Therefore, a size of the radio frequency transmitter can be reduced, and costs can be reduced.

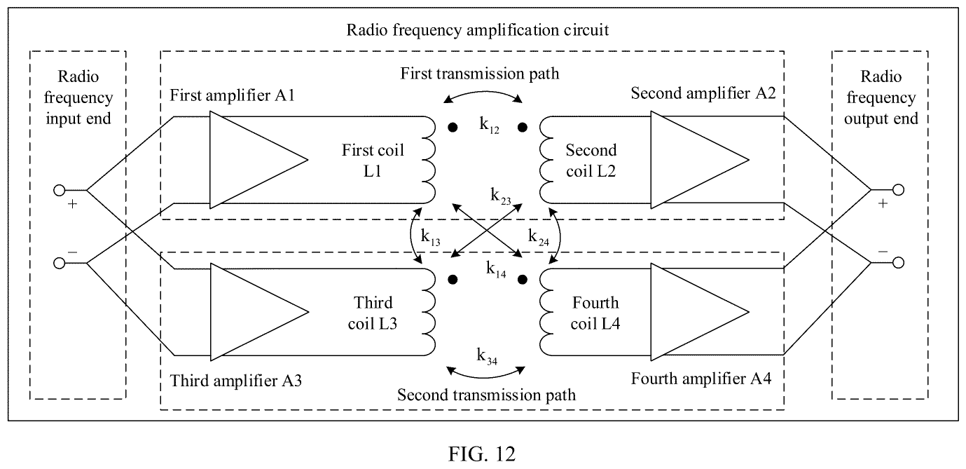

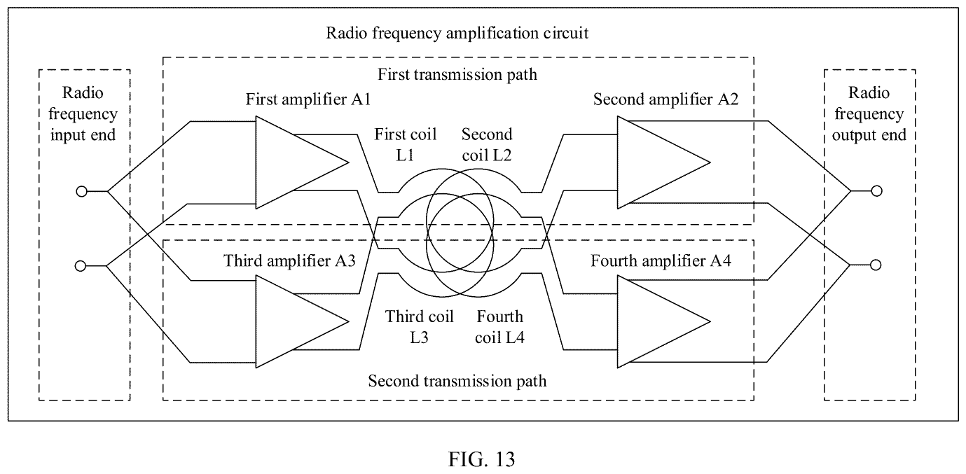

Based on the foregoing principle, as shown in FIG. 12, an embodiment of this application provides a radio frequency amplification circuit. Principles of the transformer matching network shown in FIG. 9 to FIG. 11 are also applicable to the radio frequency amplification circuit. The radio frequency amplification circuit may be applied to a transmit path or a receive path. The radio frequency amplification circuit includes a radio frequency input end, a radio frequency output end, and at least two transmission paths disposed between the radio frequency input end and the radio frequency output end. The at least two transmission paths include a first transmission path and a second transmission path. The first transmission path includes a first amplifier A1, a first coil L1, a second coil L2, and a second amplifier A2 that are sequentially coupled. The second transmission path includes a third amplifier A3, a third coil L3, a fourth coil L4, and a fourth amplifier A4 that are sequentially coupled. Any two coils of the first coil L1, the second coil L2, the third coil L3, and the fourth coil L4 are magnetically coupled to each other. In addition, conduction or cut-off of the first transmission path and the second transmission path is adjustable.

In the radio frequency amplification circuit, the radio frequency input end is configured to receive a radio frequency signal, the at least two transmission paths are configured to perform power amplification on the received radio frequency signal, and the radio frequency output end is configured to output an amplified radio frequency signal. Specifically, any amplifier of the first amplifier A1 to the fourth amplifier A4 in the first transmission path and the second transmission path may be configured to perform power amplification on the received radio frequency signal.

Optionally, a magnetic flux of coupling between any two coils of the first coil L1, the second coil L2, the third coil L3, and the fourth coil L4 may be positive or negative. In this embodiment of this application, whether the magnetic flux of coupling between any two coils is specifically positive or negative is not limited.

It may be understood that, in the first coil L1 to the fourth coil L4, when the magnetic flux of coupling between any two coils is positive, in comparison with a case in which there is no magnetic coupling between the two coils, a value of an equivalent inductance of any coil increases. When the magnetic flux of coupling between any two coils is negative, in comparison with a case in which there is no magnetic coupling between the two coils, a value of an equivalent inductance of any coil decreases.

Optionally, the first amplifier A1 to the fourth amplifier A4 may be implemented by using a transistor. For example, the transistor may be an insulated gate field effect transistor (insulated gate field effect transistor, IGFET). A specific type of the transistor is not limited in this embodiment of this application. During actual application, any amplifier of the first amplifier A1 to the fourth amplifier A4 may use an amplifier of a common-source structure, or may use an amplifier of a common-gate structure. Specific structures of the first amplifier to the fourth amplifier are not limited in this embodiment of this application.

Optionally, when the radio frequency amplification circuit includes the first transmission path and the second transmission path, the radio frequency amplification circuit may adjust the first amplifier A1 and the second amplifier A2 to be turned on or turned off, so that the first transmission path is conducted or cut off; or the radio frequency amplification circuit may adjust the third amplifier A3 and the fourth amplifier A4 to be turned on or turned off, so that the second transmission path is conducted or cut off, to adjust equivalent inductance values of the first coil L1 to the fourth coil L1 of the radio frequency amplification circuit. In this embodiment of this application, which two amplifiers are specifically adjusted to be turned on or turned off is not limited.

Optionally, when any transmission path of the first transmission path and the second transmission path is conducted, the radio frequency amplification circuit may be configured to amplify a first radio frequency signal. When the first transmission path and the second transmission path are both conducted, the radio frequency amplification circuit may be configured to amplify a second radio frequency signal. A frequency of the first radio frequency signal is higher than a frequency of the second radio frequency signal.

For example, a frequency band corresponding to the first radio frequency signal may be 37 GHz to 43.5 GHz, and a frequency band corresponding to the second radio frequency signal may be 24.25 GHz to 29.5 GHz.

Optionally, a frequency band that is of the second radio frequency signal and that is supported by the radio frequency amplification circuit provided in this embodiment of this application may include n257, n258, n259, and n260. A specific frequency band supported by the radio frequency amplification circuit is not limited in this embodiment of this application.

For example, Table 1 shows tunable effect that is obtained when the radio frequency amplification circuit provided in this embodiment of this application includes the first transmission path and the second transmission path. A tunable frequency range of the radio frequency amplification circuit includes 24.25 GHz to 29.5 GHz and 37 GHz to 43.5 GHz. When a frequency is 24.25 GHz to 29.5 GHz, a gain is 16.05 dB, an output 1 dB compression point (output power one dB compression, OP1 dB) is 15.64 dBm, and a max power added efficiency (max power added efficiency, PAEmax) is 10.66%. When a frequency is 37 GHz to 43.5 GHz, a gain is 15.52 dB, an output 1 dB compression point is 13.78 dBm, and a max power added efficiency is 16.42%.

TABLE 1

| | |
|---|---|
| Parameter | Specific Value |

| | | |
|---|---|---|
| Frequency (GHz) | 24.25-29.5 | 37-43.5 |
| Gain (dB) | 16.05 | 15.52 |
| OP1dB (dBm) | 15.64 | 13.78 |
| PAEmax (%) | 10.66 | 16.42 |

When the first transmission path is conducted and the second transmission path is cut off, the equivalent inductance value of the inductor L1 matches a capacitance value of a parasitic capacitor provided by the inductor L3, and the radio frequency amplification circuit is used for transmission of a radio frequency signal with a relatively high frequency. When the first transmission path and the second transmission path are both conducted, the equivalent inductance value of the inductor L1 changes, a changed equivalent inductance value of the inductor L1 matches an inductance value of an equivalent capacitor provided by the amplifier A1, and the radio frequency amplification circuit is used for transmission of a radio frequency signal with a relatively low frequency, and can ensure a relatively stable bandwidth of a radio frequency signal output by the radio frequency amplification circuit.

According to the radio frequency amplification circuit provided in this embodiment of this application, a plurality of transmission paths are disposed between the radio frequency input end and the radio frequency output end. The plurality of transmission paths include a plurality of magnetically coupled coils. Turn-on or turn-off of an amplifier in the transmission path is adjusted, so that conduction or cut-off of the transmission path is controlled, to change an equivalent inductance of any coil in the radio frequency amplification circuit. In addition, a corresponding equivalent capacitor is provided by using a coil or the amplifier, so that a resonance frequency of the radio frequency amplification circuit can be changed. Therefore, the radio frequency amplification circuit can support more types of multi-band systems. In addition, according to the radio frequency amplification circuit provided in this embodiment of this application, an equivalent inductor and an equivalent capacitor are both adjusted, and a value of the equivalent inductor matches a value of the equivalent capacitor. This can ensure that a quality factor remains unchanged, and therefore can ensure a relatively stable bandwidth. When the radio frequency transmitter uses the radio frequency amplification circuit, in comparison with the radio frequency transmitter shown in FIG. 1, when a single transmit path or a single receive path in the radio frequency transmitter uses the radio frequency amplification circuit, a plurality of transmission paths are disposed in the radio frequency amplification circuit, so that a multi-band system can be supported. A plurality of transmit paths or a plurality of receive paths do not need to be independently disposed, and another component on the transmit path or the receive path does not need to be disposed, for example, a matching network, a filter, or another component. Therefore, a size of the radio frequency transmitter can be reduced, and costs can be reduced.

In a possible implementation, as shown in FIG. 13, the first coil L1, the second coil L2, the third coil L3, and the fourth coil L4 in the radio frequency amplification circuit may be symmetrically disposed at at least one trace layer.

Optionally, an inductance value of the first coil L1 is equal to an inductance value of the third coil L3, and an inductance value of the second coil L2 is equal to an inductance value of the fourth coil L4.

Optionally, a mutual inductance between the first coil L1 and the second coil L2 is equal to a mutual inductance between the third coil L3 and the fourth coil L4; and/or a mutual inductance between the first coil L1 and the third coil L3 is equal to a mutual inductance between the second coil L2 and the fourth coil L4; and/or a mutual inductance between the first coil L1 and the fourth coil L4 is equal to a mutual inductance between the second coil L2 and the third coil L3.

Optionally, the first amplifier A1 and the third amplifier A3 are amplifiers whose amplification factors are the same, and the second amplifier A2 and the fourth amplifier A4 are amplifiers whose amplification factors are the same.

According to the radio frequency amplification circuit provided in this embodiment of this application, the first coil L1 to the fourth coil L4 are symmetrically disposed, inductance values of the first coil L1 to the fourth coil L4 are set to a same value, mutual inductances between the coils are set to a same value, and amplification factors of amplifiers are set to a same value, so that radio frequency signals obtained after power amplification in the first transmission path and the second transmission path have a same amplitude, and signals output by the first transmission path and the second transmission path can be better fused.

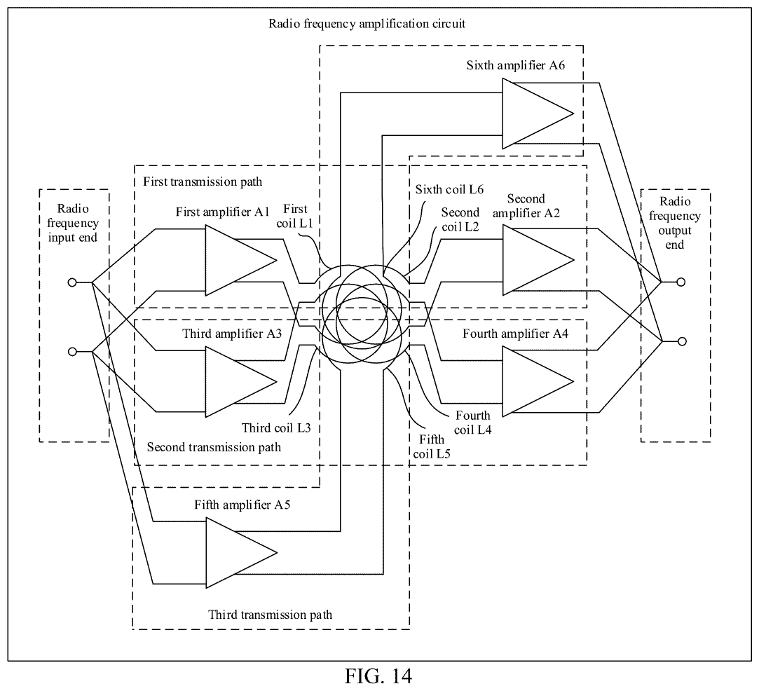

Further, in addition to the first transmission path and the second transmission path, the radio frequency amplification circuit may further include more transmission paths. A quantity of transmission paths is not specifically limited in this embodiment of this application. In a possible implementation, as shown in FIG. 14, the radio frequency amplification circuit may further include a third transmission path disposed between the radio frequency input end and the radio frequency output end. The third transmission path includes a fifth amplifier A5, a fifth coil L5, a sixth coil L6, and a sixth amplifier A6 that are sequentially coupled. Any two coils of the first coil L1, the second coil L2, the third coil L3, the fourth coil L4, the fifth coil L5, and the sixth coil L6 are magnetically coupled to each other.

Optionally, an inductance value of the fifth coil L5 may be equal to inductance values of the first coil L1 and the second coil L3, and an inductance value of the sixth coil L6 may be equal to inductance values of the second coil L2 and the fourth coil L4. Specific inductance values of the fifth coil L5 and the sixth coil L6 are not limited in this embodiment of this application.

Optionally, a mutual inductance between the fifth coil L5 and the sixth coil L6 may be equal to a mutual inductance between the first coil L1 and the second coil L2; and/or a mutual inductance between the fifth coil L5 and the second coil L2 may be equal to a mutual inductance between the first coil L1 and the sixth coil L6; and/or a mutual inductance between the fifth coil L5 and the first coil L1 may be equal to a mutual inductance between the second coil L2 and the sixth coil L6.

Optionally, a magnetic flux of coupling between any two coils of the first coil L1, the second coil L2, the third coil L3, the fourth coil L4, the fifth coil L5, and the sixth coil L6 may be positive or negative. In this embodiment of this application, whether the magnetic flux of coupling between the two coils is specifically positive or negative is not limited. In the following embodiments, an example in which the magnetic flux of any two coils is positive is used for description.

Optionally, the first coil L1, the second coil L2, the third coil L3, the fourth coil L4, the fifth coil L5, and the sixth coil L6 may be symmetrically disposed at at least one trace layer.

Optionally, when the radio frequency amplification circuit includes a plurality of transmission paths, turn-on or turn-off of amplifiers in different transmission paths is controlled, so that an equivalent inductor and an equivalent capacitor of the radio frequency amplification circuit can be adjusted, to adjust a resonance frequency of the radio frequency amplification circuit. In this way, the radio frequency amplification circuit can support transmission of radio frequency signals of more frequency bands.

For example, the radio frequency amplification circuit includes the first transmission path, the second transmission path, and the third transmission path, the first transmission path includes the first coil L1 and the second coil L2, the second transmission path includes the third coil L3 and the fourth coil L4, the third transmission path includes the fifth coil L5 and the sixth coil L6, the inductance values of the first coil L1 and the third coil L3 are equal, the inductance values of the second coil L2 and the fourth coil L4 are equal, the inductance value of the fifth coil L5 is greater than the inductance value of the first coil L1, and the inductance value of the sixth coil is greater than the inductance value of the second coil L2. When the first transmission path is conducted and the second transmission path and the third transmission path are cut off, the resonance frequency of the radio frequency amplification circuit may be 25 GHz. When the first transmission path and the second transmission path are conducted and the third transmission path is cut off, the resonance frequency of the radio frequency amplification circuit may be 20 GHz. When the first transmission path and the third transmission path are conducted and the second transmission path is cut off, the resonance frequency of the radio frequency amplification circuit may be 15 GHz. When the first transmission path, the second transmission path, and the third transmission path are all conducted, the resonance frequency of the radio frequency amplification circuit may be 10 GHz.

According to the radio frequency amplification circuit provided in this embodiment of this application, conduction or cut-off of at least two transmission paths is adjusted, so that the equivalent inductor and the equivalent capacitor of the radio frequency amplification circuit can be adjusted, to adjust the resonance frequency of the radio frequency amplification circuit. When the radio frequency amplification circuit includes a plurality of transmission paths, the resonance frequency of the radio frequency amplification circuit may be adjusted to a plurality of values, so that the radio frequency amplification circuit can support a plurality of types of multi-band systems.

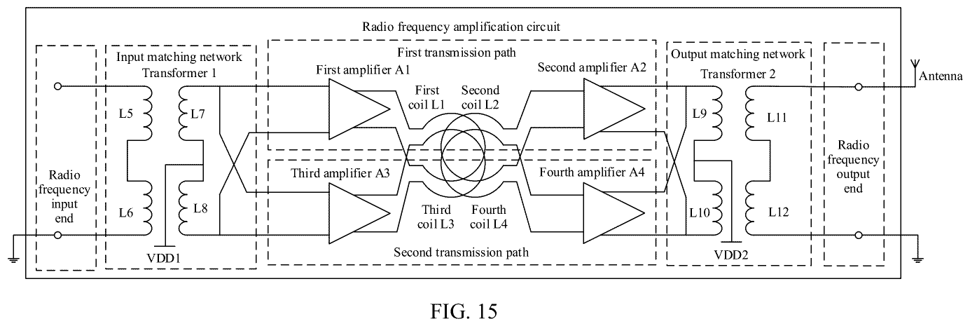

In a possible implementation, as shown in FIG. 15, the radio frequency amplification circuit further includes an input matching network and an output matching network. The input matching network is coupled between the radio frequency input end and the at least two transmission paths, and the output matching network is coupled between the radio frequency output end and the at least two transmission paths.

During actual application, the radio frequency amplification circuit may include a part or all of the structure shown in FIG. 15, and may further include another functional circuit. This is not specifically limited in this embodiment of this application.

The input matching network is configured to receive a radio frequency signal, process the radio frequency signal, and input a processed radio frequency signal to the radio frequency input end. The output matching network is configured to process the radio frequency signal output by the radio frequency output end.

Optionally, the input matching network and the output matching network may be a transformer 1 and a transformer 2 shown in FIG. 15. The transformer 1 includes a coil L5 to a coil L8. One end of the coil L5 is coupled to one end of the coil L6, the other end of the coil L5 is coupled to the radio frequency input end, the other end of the coil L6 is coupled to a ground end by using the radio frequency input end, and one end of the coil L7 is coupled to one end of the coil L8. A coupling end of the coil L7 and the coil L8 is configured to receive first tap inductor center feeding (VDD1). The other end of the coil L7 and the other end of the coil L8 are coupled to the first amplifier A1 and the third amplifier A3. The transformer 2 includes a coil L9 to a coil L12. One end of the coil L9 is coupled to one end of the coil L10. A coupling end of the coil L9 and the coil L10 is configured to receive second tap inductor center feeding (VDD2). The other end of the coil L9 and the other end of the coil L10 are coupled to the second amplifier A2 and the fourth amplifier A4. One end of the coil L11 is coupled to one end of the coil L12, the other end of the coil L11 is coupled, by using the radio frequency output end, to an antenna configured to send a radio frequency signal, and the other end of the coil L12 is coupled, by using the radio frequency output end, to a ground end. The first receive tap inductor center feeding is used to provide power supply voltages of the first amplifier A1 and the third amplifier A3, and the second tap inductor center feeding is used to provide power supply voltages of the second amplifier A2 and the fourth amplifier A4. Specific types of the input matching network and the output matching network are not limited in this embodiment of this application.

According to the radio frequency amplification circuit provided in this embodiment of this application, the input matching network and the output matching network are disposed, so that output power of the radio frequency amplification circuit can be maximized.

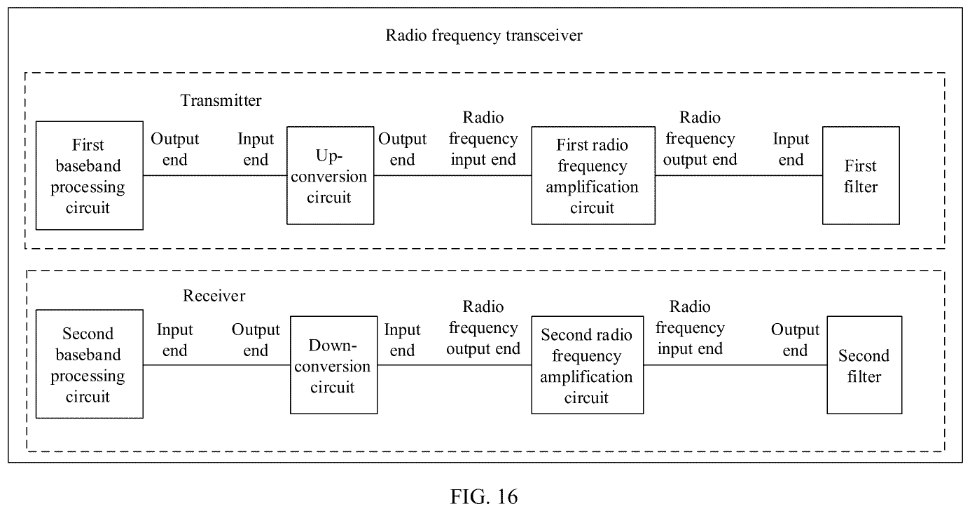

As shown in FIG. 16, an embodiment of this application further provides a radio frequency transceiver. The radio frequency transceiver includes a transmitter and/or a receiver. The transmitter and/or the receiver include/includes a radio frequency amplification circuit and a filter that are sequentially coupled. The radio frequency amplification circuit is the radio frequency amplification circuit in FIG. 12 to FIG. 15.

Optionally, the radio frequency transceiver includes the transmitter, a radio frequency amplification circuit included in the transmitter is a first radio frequency amplification circuit, a filter included in the transmitter is a first filter, and a radio frequency output end of the first radio frequency amplification circuit is coupled to an input end of the first filter.

Optionally, the transmitter further includes a first baseband processing circuit and an up-conversion circuit. An output end of the up-conversion circuit is coupled to a radio frequency input end of the first radio frequency amplification circuit, and an input end of the up-conversion circuit is coupled to an output end of the first baseband processing circuit.

Optionally, the radio frequency transceiver includes the receiver, a radio frequency amplification circuit included in the receiver is a second radio frequency amplification circuit, a filter included in the receiver is a second filter, and an output end of the second filter is coupled to a radio frequency input end of the second radio frequency amplification circuit.

Optionally, the receiver further includes a down-conversion circuit and a second baseband processing circuit. An input end of the down-conversion circuit is coupled to a radio frequency output end of the second radio frequency amplification circuit, and an output end of the down-conversion circuit is coupled to an input end of the second baseband processing circuit.

Optionally, the first baseband processing circuit and the second baseband processing circuit may be a same baseband processing circuit.

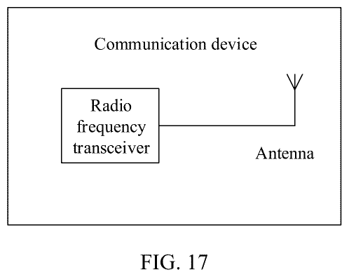

As shown in FIG. 17, an embodiment of this application further provides a communication device. The communication device includes an antenna and a radio frequency transceiver coupled to the antenna. The antenna is configured to transmit and receive a radio frequency signal. The radio frequency transceiver is the transceiver shown in FIG. 16.

The foregoing descriptions are merely specific implementations of this application, but are not intended to limit the protection scope of this application. Any variation or replacement within the technical scope disclosed in this application shall fall within the protection scope of this application. Therefore, the protection scope of this application shall be subject to the protection scope of the claims.

What is claimed is:

1. A radio frequency transceiver comprising a transmitter and/or a receiver, wherein the transmitter and/or the receiver comprise/comprises a radio frequency amplification circuit and a filter that are sequentially coupled,
the radio frequency amplification circuit comprises a radio frequency input end, a radio frequency output end, and at least two transmission paths disposed between the radio frequency input end and the radio frequency output end;
the at least two transmission paths comprise a first transmission path and a second transmission path,
wherein the first transmission path comprises a first amplifier, a first coil, a second coil, and a second amplifier that are sequentially coupled, and
wherein the second transmission path comprises a third amplifier, a third coil, a fourth coil, and a fourth amplifier that are sequentially coupled; and
any two coils of the first coil, the second coil, the third coil, and the fourth coil are magnetically coupled to each other,
wherein turn-on or turn-off of the first amplifier and the second amplifier is adjustable, or turn-on or turn-off of the third amplifier and the fourth amplifier is adjustable.

2. The radio frequency transceiver according to claim 1, wherein based on any transmission path of the first transmission path and the second transmission path conducting, the radio frequency amplification circuit is configured to amplify a first radio frequency signal; or
based on the first transmission path and the second transmission path both conducting, the radio frequency amplification circuit is configured to amplify a second radio frequency signal, wherein a frequency of the first radio frequency signal is higher than a frequency of the second radio frequency signal.

3. The radio frequency transceiver according to claim 2, wherein an inductance value of the first coil is equal to an inductance value of the third coil, and an inductance value of the second coil is equal to an inductance value of the fourth coil.

4. The radio frequency transceiver according to claim 1, wherein a mutual inductance between the first coil and the second coil is equal to a mutual inductance between the third coil and the fourth coil; and/or
a mutual inductance between the first coil and the third coil is equal to a mutual inductance between the second coil and the fourth coil; and/or
a mutual inductance between the first coil and the fourth coil is equal to a mutual inductance between the second coil and the third coil.

5. The radio frequency transceiver according to claim 1, wherein the first amplifier and the third amplifier are amplifiers whose amplification factors are the same, and the second amplifier and the fourth amplifier are amplifiers whose amplification factors are the same.

6. The radio frequency transceiver according to claim 5, wherein the at least two transmission paths further comprise a third transmission path, wherein the third transmission path comprises a fifth amplifier, a fifth coil, a sixth coil, and a sixth amplifier, and wherein any two coils of the first coil, the second coil, the third coil, the fourth coil, the fifth coil, and the sixth coil are magnetically coupled to each other.

7. The radio frequency transceiver according to claim 6, wherein the first coil, the second coil, the third coil, the fourth coil, the fifth coil, and the sixth coil are symmetrically disposed on at least one trace layer.

8. The radio frequency transceiver according to claim 1, wherein the radio frequency amplification circuit further comprises an input matching network and an output matching network, wherein the input matching network is coupled between the radio frequency input end and the at least two transmission paths, and wherein the output matching network is coupled between the radio frequency output end and the at least two transmission paths.

9. The radio frequency transceiver according to claim 8, wherein the radio frequency transceiver comprises the transmitter, the radio frequency amplification circuit comprised in the transmitter is a first radio frequency amplification circuit, the filter comprised in the transmitter is a first filter, and an output end of the first radio frequency amplification circuit is coupled to an input end of the first filter.

10. The radio frequency transceiver according to claim 9, wherein the transmitter further comprises a first baseband processing circuit and an up-conversion circuit, wherein an output end of the up-conversion circuit is coupled to an input end of the first radio frequency amplification circuit, and wherein an input end of the up-conversion circuit is coupled to an output end of the first baseband processing circuit.

11. The radio frequency transceiver according to claim 9, wherein the radio frequency transceiver comprises the receiver, wherein the radio frequency amplification circuit comprised in the receiver is a second radio frequency amplification circuit, wherein the filter comprised in the receiver is a second filter, and wherein an output end of the second filter is coupled to an input end of the second radio frequency amplification circuit.

12. The radio frequency transceiver according to claim 11, wherein the receiver further comprises a down-conversion circuit and a second baseband processing circuit, wherein an input end of the down-conversion circuit is coupled to an output end of the second radio frequency amplification circuit, and wherein an output end of the down-conversion circuit is coupled to an input end of the second baseband processing circuit.

13. A communication device comprising an antenna and a radio frequency transceiver coupled to the antenna, wherein the antenna is configured to transmit or receive a radio frequency signal,
the radio frequency transceiver comprises a transmitter and/or a receiver, wherein the transmitter and/or the receiver comprise/comprises a radio frequency amplification circuit and a filter that are sequentially coupled;
the radio frequency amplification circuit comprises a radio frequency input end, a radio frequency output end, and at least two transmission paths disposed between the radio frequency input end and the radio frequency output end,
wherein the at least two transmission paths comprise a first transmission path and a second transmission path,
wherein the first transmission path comprises a first amplifier, a first coil, a second coil, and a second amplifier that are sequentially coupled, and
wherein the second transmission path comprises a third amplifier, a third coil, a fourth coil, and a fourth amplifier that are sequentially coupled; and
any two coils of the first coil, the second coil, the third coil, and the fourth coil are magnetically coupled to each other,
wherein turn-on or turn-off of the first amplifier and the second amplifier is adjustable, or turn-on or turn-off of the third amplifier and the fourth amplifier is adjustable.

14. The communication device according to claim 13, wherein based on any transmission path of the first transmission path and the second transmission path conducting, the radio frequency amplification circuit is configured to amplify a first radio frequency signal; or
based on the first transmission path and the second transmission path both conducting, the radio frequency amplification circuit is configured to amplify a second radio frequency signal, wherein a frequency of the first radio frequency signal is higher than a frequency of the second radio frequency signal.

15. The communication device according to claim 14, wherein an inductance value of the first coil is equal to an inductance value of the third coil, and an inductance value of the second coil is equal to an inductance value of the fourth coil.

16. The communication device according to claim 13, wherein a mutual inductance between the first coil and the second coil is equal to a mutual inductance between the third coil and the fourth coil; and/or
a mutual inductance between the first coil and the third coil is equal to a mutual inductance between the second coil and the fourth coil; and/or
a mutual inductance between the first coil and the fourth coil is equal to a mutual inductance between the second coil and the third coil.

17. The communication device according to claim 13, wherein the first amplifier and the third amplifier are amplifiers whose amplification factors are the same, and the second amplifier and the fourth amplifier are amplifiers whose amplification factors are the same.

18. The communication device according to claim 17, wherein the at least two transmission paths further comprise a third transmission path, wherein the third transmission path comprises a fifth amplifier, a fifth coil, a sixth coil, and a sixth amplifier, and wherein any two coils of the first coil, the second coil, the third coil, the fourth coil, the fifth coil, and the sixth coil are magnetically coupled to each other.

19. The communication device according to claim 18, wherein the first coil, the second coil, the third coil, the fourth coil, the fifth coil, and the sixth coil are symmetrically disposed at at least one trace layer.

20. The communication device according to claim 13, wherein the radio frequency amplification circuit further comprises an input matching network and an output matching network, wherein the input matching network is coupled between the radio frequency input end and the at least two transmission paths, and wherein the output matching network is coupled between the radio frequency output end and the at least two transmission paths.
